(19) United States
(12) Patent Application Publication
(10) Pub. No.: US 2026/0114279 A1
(43) Pub. Date: Apr. 23, 2026

(54) COOLING APPARATUS FOR POWER MODULE

(71) Applicant: HYUNDAI MOBIS CO., LTD., Seoul (KR)

(72) Inventor: Keun Jae LEE, Yongin-si (KR)

(73) Assignee: HYUNDAI MOBIS CO., LTD., Seoul (KR)

(21) Appl. No.: 19/293,235

(22) Filed: Aug. 7, 2025

(30) Foreign Application Priority Data
Oct. 23, 2024 (KR) 10-2024-0145926

(51) Int. Cl. H01L 23/473; H01L 23/00; H01L 23/29; H01L 23/31; H01L 23/367; H01L 25/07; H10D 80/20

(52) U.S. Cl. CPC H10W 40/47; H10W 40/228; H10W 74/114; H10W 74/47; H10W 90/00; H10D 80/20; H10D 80/251; H10W 72/07351; H10W 72/30

(57) ABSTRACT

A cooling apparatus for a power module is provided. The cooling apparatus includes: a power module including power element chips, and a circuit substrate bonded to the power element chips; a heat sink in contact with the circuit substrate, the heat sink having through-holes formed therein; and a manifold configured to allow cooling fluid to flow therethrough and including a wall portion in contact with the circuit substrate. The wall portion includes at least two or more extended ends that extend in a flow direction of the cooling fluid, and a closed end connected to each of the extended ends. The extended ends partly or completely overlap the power element chips.

### CROSS-REFERENCE TO RELATED APPLICATION

This application claims priority to and the benefit under 35 USC § 119(a) of Korean Patent Application No. 10-2024-0145926, filed on Oct. 23, 2024, in the Korean Intellectual Property Office, the disclosure of which is incorporated herein by reference in its entirety for all purposes.

### BACKGROUND

### 1. Field

The present disclosure relates to a cooling apparatus for a power module, configured to cool the power module using cooling fluid.

### 2. Description of the Related Art

A power module is applied to an electric vehicle and the like to control a high voltage and a large current. As a result, since a substantially large amount of heat is generated, appropriate cooling needs to be performed so as to maintain performance and durability of the power module. To this end, cooling fluid is used to cool the power module, or waste heat from the power module is used to heat a vehicle.

In the related art, a cooling apparatus is commonly connected to a side surface of a power module, and cooling fluid from the cooling apparatus flows through the power module, thereby cooling the power module. However, in the case of the conventional cooling apparatus, there is a problem in that cooling efficiency is not high because a commonly available simple tube structure or fin structure is applied to the cooling apparatus.

The information included in this background of the present disclosure is only for enhancement of understanding of the general background of the present disclosure and may not be taken as an acknowledgement or any form of suggestion that this information forms the prior art already known to a person skilled in the art.

### SUMMARY

Therefore, the present disclosure has been made in view of the above problems, and it is an aspect of the present disclosure to provide a cooling apparatus for a power module, the cooling apparatus including a manifold provided for cooling of the power module. When cooling fluid flows through the inside of the manifold, the power module exchanges heat with the cooling fluid such that the power module is cooled, thereby improving cooling efficiency through a structural configuration optimized for cooling of a heat-generating element in the power module.

The aspects of the present disclosure are not limited to the above-mentioned aspects, and other technical aspects not mentioned herein will be clearly understood by those skilled in the art to which the present disclosure pertains from the detailed description of the embodiments.

In a general aspect, a cooling apparatus for a power module, includes: a power module including: power element chips; and a circuit substrate bonded to the power element chips; a heat sink in contact with the circuit substrate, the heat sink having a plurality of through-holes formed therein; and a manifold configured to allow cooling fluid to flow therethrough and including a wall portion in contact with the circuit substrate, wherein the wall portion includes at least two or more extended ends that extend in a flow direction of the cooling fluid, and a closed end connected to each of the extended ends, and wherein the extended ends are configured to partly or completely overlap the power element chips.

The through-holes may extend in a direction intersecting the flow direction of the cooling fluid.

The wall portion of the manifold may form an inlet-side channel and an outlet-side channel by connecting the closed end to ends of the extended ends, wherein the cooling fluid may flow from the inlet-side channel to the outlet-side channel through the through-holes.

The power module may include a plurality of the power element chips, wherein the respective power element chips may be spaced apart from each other and arranged to overlap the extended ends.

The manifold may include the extended ends extending in pairs, the pair of extended ends being connected to the closed end, wherein the respective power element chips may be arranged to be spaced apart from each other at different extended ends.

The power element chips may be provided in an even number, wherein the respective power element chips may be arranged on the pair of extended ends and spaced apart from each other.

The power element chips may be disposed to overlap portions of the heat sink, the portions having the through-holes formed therein.

The power element chips or the extended ends may be configured such that an area of each of the power element chips or a thickness of each of the extended ends is set according to an amount of heat generated by the power element chips.

The respective extended ends of the wall portion of the manifold may extend to gradually approach each other with an angle formed therebetween.

The through-holes in the heat sink may extend diagonally relative to the flow direction of the cooling fluid in an outward direction opposite to an inward direction in which the respective extended ends connected to each other through the closed end face each other.

The wall portion of the manifold may be configured such that a plurality of the extended ends and a plurality of the closed ends alternately connect ends located on one side of the extended ends and ends located on other side of the extended ends, wherein the ends may be respectively located on the one side and the other side being located on different extended ends, thereby forming a plurality of inlet-side channels and a plurality of outlet-side channels.

The wall portion of the manifold may be configured such that a number of the closed ends connected to the one side of the extended ends is one less than a number of the closed ends connected to the other side of the extended ends.

The power element chips may be arranged to overlap two or more of the extended ends.

One surface of the heat sink may be in contact with the power module, another surface thereof may have the through-holes formed therein, and the heat sink may be interposed between the power module and the manifold to form a heat transfer structure.

The power module may include a molding part made of an epoxy material and configured to surround the power element chips and the circuit substrate, wherein the molding part may include the wall portion of the manifold.

In another general aspect, a cooling apparatus includes: a power module including a power element chip, and a circuit substrate bonded to the power element chips; a heat sink in contact with the circuit substrate; and a manifold including a wall portion in contact with the heat sink, the wall portion configured to draw heat from the heat sink, the manifold configured to direct cooling fluid therethrough and dissipate heat, wherein the wall portion includes extended ends that extend in a flow direction of the cooling fluid, and a closed end connected to each of the extended ends, and wherein the extended ends is configured to partly or completely overlap the power element chips.

The heat sink may include a plurality of through-holes.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a view showing a cooling apparatus for a power module according to one embodiment;

FIG. 2 is a cross-sectional view of the cooling apparatus for a power module according to one embodiment;

FIG. 3 is a view showing one embodiment of a manifold in the cooling apparatus for a power module according to the present disclosure;

FIG. 4 is view showing another embodiment of the manifold in the cooling apparatus for a power module according to the present disclosure;

FIG. 5 is a view showing one embodiment of the manifold in the cooling apparatus for a power module according to the present disclosure;

FIG. 6 is a view showing another embodiment of the manifold in the cooling apparatus for a power module according to the present disclosure; and

FIG. 7 is a view showing still another embodiment of the manifold in the cooling apparatus for a power module according to the present disclosure.

### DETAILED DESCRIPTION

In describing the embodiments disclosed herein, when it is determined that a detailed description of publicly known techniques to which the disclosure pertains may obscure the gist of the present disclosure, the detailed description will be omitted. Further, it should be understood that the accompanying drawings are merely illustrated to easily describe the embodiments disclosed in this specification, and therefore, the technical idea disclosed in this specification is not limited by the accompanying drawings. Further, it should be noted that the accompanying drawings include all modifications, equivalents, and substitutes that fall within the spirit and technical scope of the present disclosure. The disclosure below is not intended to limit the present disclosure to a form described in the present disclosure or to a specific field, and it is contemplated that various alternative aspects and modifications to the present disclosure are possible, whether explicitly described or implied herein. It will be appreciated by those skilled in the art to which the present disclosure pertains that the form and details of the present disclosure may vary.

The present disclosure will be described with reference to specific aspects. However, as will be appreciated by those skilled in the art to which the present disclosure pertains, various aspects disclosed herein may be modified or otherwise implemented in various other ways without departing from the spirit and scope of the disclosure. Accordingly, the following description is to be considered as illustrative and is for the purpose of teaching those skilled in the art the manner of making and using various embodiments. It is to be understood that the forms of disclosure herein shown and described are to be taken as representative embodiments. Equivalent elements, materials, processes, or steps may be substituted for those representatively illustrated and described herein. Expressions such as “including”, “comprising”, “incorporating”, “consisting of”, “have”, and “is” used to describe and claim the present disclosure are intended to be construed in a non-exclusive manner, that is, to allow for items, components or elements not explicitly described herein to be present. Reference to the singular is also to be construed to relate to the plural.

Further, various embodiments disclosed herein are to be taken in the illustrative and explanatory sense and should not be construed as limiting the scope of the present disclosure. All references to joining (for example, attached, affixed, coupled, connected, and the like) are only used to aid the reader's understanding of the present disclosure and are not intended to limit the position, orientation, or use of a configuration and/or methods disclosed herein. Therefore, references to joining, if any, are to be construed broadly. Moreover, such references to joining do not necessarily imply that two or more elements are directly connected to each other. Additionally, all numerical terms, such as, but not limited to, “first”, “second”, “third”, “primary”, “secondary”, “main” or any other ordinary and/or numerical terms, should also be taken only as identifiers, to assist the reader's understanding of the various elements, embodiments, variations and/or modifications of the present disclosure, and may not create any limitations, particularly as to any component, embodiment, variation, and/or modification, or the order or preference thereof. That is, while these expressions may be used to describe various components, the components are not limited by the corresponding expressions. These expressions are used only for the purpose of distinguishing one component from another.

Hereinafter, the suffixes “module”, “unit”, and “part” for components used in the following description are merely provided for facilitation of preparing this specification. Therefore, the suffixes themselves do not have significant meanings or roles.

When one component is referred to as being “connected” or “joined” to another component, the one component may be directly connected or joined to the other component, but it should be understood that other components may be present therebetween. On the other hand, when the one component is referred to as being “directly connected to” or “directly in contact with” the other component, it should be understood that no other components are present therebetween.

Any number of components or a variety of components in any of the configurations described herein may be included in the present disclosure. The components may include any combination of the features described herein, and may be arranged in any of the various configurations described herein. The structure and arrangement of components of the present disclosure, as well as the concepts regarding the use and operation of the components, may be applied not only to the specific embodiments discussed herein, but also to any number of embodiments in any combination. Embodiments including those having various features in various arrangements are described below with reference to the drawings.

Hereinafter, various embodiments disclosed herein will be described in detail with reference to the accompanying drawings, and regardless of the drawing symbols, the same or similar components will be denoted by the same reference numerals, and redundant descriptions thereof will be omitted.

A cooling apparatus for a power module according to the present disclosure is intended to improve cooling efficiency of a power element chip 110 provided in a power module 100. The power module 100 is connected to a manifold 300 with a heat sink 200 interposed therebetween, and cooling fluid flowing through the inside of the manifold 300 exchanges heat with the power module 100 with the heat sink 200 interposed therebetween, thereby cooling the power element chip 110.

In particular, the present disclosure proposes a cooling apparatus for a power module, configured to optimize arrangement of the power element chip 110 and a wall portion 310 of the manifold 300 so as to improve cooling efficiency of the power element chip 110, and to reduce the overall size of a structure.

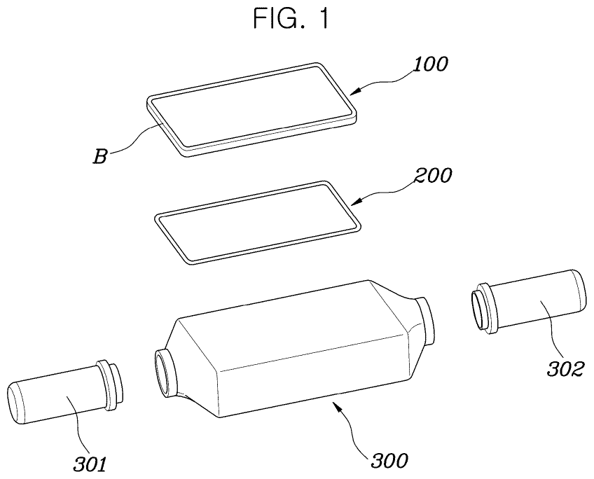

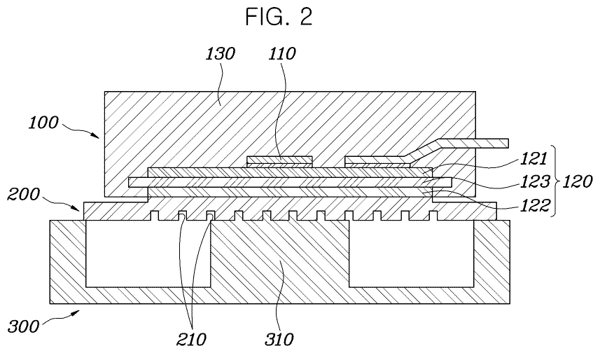

FIG. 1 is a view showing a cooling apparatus for a power module according to one embodiment of the present disclosure, and FIG. 2 is a view showing a cross section of the power module 100, the heat sink 200, and the manifold 300.

The cooling apparatus for a power module according to one embodiment of the present disclosure includes the power module 100, the heat sink 200, and the manifold 300. FIGS. 1 and 2 are schematic views showing main components related to the present disclosure, and more or fewer components may be included in actual implementation.

The cooling apparatus for the power module 100 according to one embodiment of the present disclosure includes the power module 100 provided with the power element chip 110 and a circuit substrate 120 configured for the power element chip 110 to be bonded thereto, the heat sink 200 in contact with the circuit substrate 120 of the power module 100, the heat sink having a plurality of through-holes 210 formed therein, and the manifold 300 configured for cooling fluid to flow therethrough and formed to have a wall portion 310 in contact with the circuit substrate 120. The wall portion 310 is formed of at least two or more extended ends 320 extending in the flow direction of cooling fluid and a closed end 330 connected to each of the extended ends 320, and the extended ends 320 are formed to partly or fully overlap the power element chips 110.

In the power module 100, the circuit substrate 120 may include a first substrate 121 and a second substrate 122, and each of the substrates 121 and 122 may include an insulating layer 123. The first substrate 121 is a substrate disposed on the upper side in FIG. 2, the second substrate 122 is a substrate disposed on the lower side in FIG. 2, and the insulating layer 123 is provided between the first substrate 121 and the second substrate 122 so as to conduct heat to each of the substrates. A metal circuit may be formed on each of the substrates 121 and 122, and the metal circuit may be formed of a copper material so as to form an electrical connection structure through a pattern. The insulating layer 123 may be formed of a ceramic material, may block electrical connection between the first substrate 121 and the second substrate 122, and may perform heat conduction.

In the present disclosure, the power element chip 110 may be mounted on the first substrate 121, and the power element chip 110 may be a switching element such as an insulated gate bipolar transistor (IGBT), a metal-oxide-semiconductor field-effect transistor (MOSFET), or the like.

In addition, the power module 100 includes an epoxy molding part 130 surrounding the power element chip 110 and the circuit substrate 120, thereby protecting internal components including the power element chip 110 and the circuit substrate 120 from the outside. The molding part 130 is disposed to include the wall portion 310 of the manifold 300, so that the power element chip 110 may be disposed in an area in which a cooling effect is generated by the wall portion 310.

The heat sink 200 may be made of a material having excellent thermal conductivity. For example, the heat sink may be made of copper or aluminum. The heat sink 200 may be configured to be in contact with the circuit substrate 120 of the power module 100 and may enable heat conduction between cooling fluid flowing through the manifold 300 and the power module 100.

The heat sink 200 may have one side in contact with the power module 100, may have the through-holes 210 formed in the other side thereof, and may be interposed between the power module 100 and the manifold 300 to form a heat transfer structure. That is, the heat sink 200 may have one side in contact with the circuit substrate 120 of the power module 100 and the other side in contact with the wall portion 310 of the manifold 300. Here, the cooling fluid flowing through the inside of the manifold 300 may pass through the wall portion 310 through the through-holes 210 formed in the other side of the heat sink. Accordingly, the heat sink 200 may cool the power module 100 by cooling performance when the cooling fluid passes through the wall portion 310 of the manifold 300.

Here, the heat sink 200 may be formed such that the through-holes 210 extend in a direction intersecting a direction in which the cooling fluid flows.

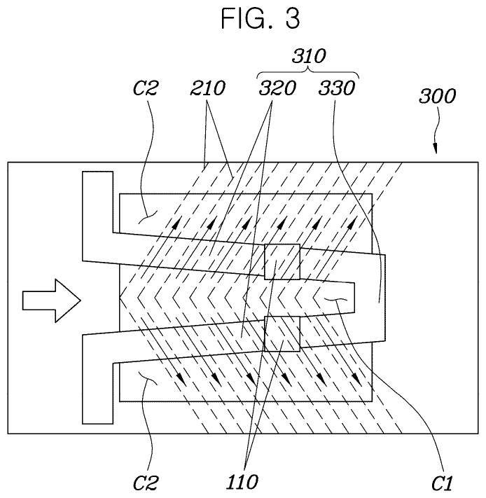

Referring to FIG. 3, the flow direction of the cooling fluid may be from the left side to the right side based on the drawing. Here, the through-holes 210 in the heat sink 200 may extend in the upward-and-downward direction intersecting the direction in which the cooling fluid flows and may be arranged in the direction in which the cooling fluid flows. In addition, the through-holes 210 may be formed in portions of the heat sink 200 which are in contact with the wall portion 310 of the manifold 300.

The manifold 300 is formed to allow the cooling fluid to flow through the inside thereof. The manifold 300 may have an inlet 301 into which the cooling fluid is introduced and an outlet 302 through which the cooling fluid is discharged.

In the present disclosure, the cooling fluid may be, for example, a liquid coolant, and various fluids capable of performing heat exchange, including air, may be employed.

The manifold 300 may be made of a polymer material such as a thermoplastic elastomer (TPE).

The wall portion 310 is formed inside the manifold 300 and is configured to change the flow direction of the cooling fluid. As shown in FIG. 3, the wall portion 310 may be formed of at least two or more extended ends 320 and the closed end 330 connecting the respective extended ends 320 to each other. In this case, the extended ends 320 and the closed end 330 may guide the flow of the cooling fluid and may change the flow direction of the cooling fluid so as to allow the cooling fluid to flow through the through-holes 210 in the heat sink 200, thereby generating a cooling effect.

That is, when the cooling fluid flows through the inside of the manifold 300, the cooling fluid may flow a space formed between the respective extended ends 320 forming the wall portion 310, and the flow direction of the cooling fluid may be changed by the closed end 330 so as to allow the cooling fluid to flow through the through-holes 210 in the heat sink 200. Through such a process, a jet impingement cooling structure may be achieved when the cooling fluid passes through the through-holes 210 in the heat sink 200.

In particular, in the present disclosure, the power element chips 110 of the power module 100 and the extended ends 320 of the wall portion 310 may be formed to partially or fully overlap each other. Here, the power element chips 110 and the extended ends 320 may be configured to overlap each other through the position of each of the power element chips 110 mounted on the circuit substrate 120 or the shape of each of the extended ends 320 of the wall portion 310. In this manner, when the power element chips 110 and the extended ends 320 overlap each other, cooling efficiency may be improved by concentrating a cooling effect on the power element chips 110 that substantially generate heat.

Here, an area in which the power element chip 110 and the extended end 320 overlap each other may be configured to be at least 5% or more of the area of the power element chip 110. In this manner, according to the present disclosure, the power element chips 110 may be efficiently cooled through the manifold 300 optimally applied to the present disclosure for cooling of the power element chips 110 in the power module 100. Further, since cooling is intensively performed on the heat-generating area of the power element chips 110, the size of a package for cooling may be reduced, and performance of the power module 100 may be improved through efficient cooling.

In the present disclosure, the power module 100 is described as employing a single-sided cooling method, but a plurality of circuit substrates 120 may be configured to be symmetrically arranged spaced apart from each other with the power element chip 110 interposed therebetween, thereby implementing a double-sided cooling method. In the case of the double-sided cooling method, heat generated from the power element chip 110 is released to the outside through the substrates respectively disposed on both sides of the power element chip 110, so that heat dissipation is performed in both directions. Meanwhile, in the case of the single-sided cooling method according to the present disclosure, heat dissipation of the power element chip is performed in one direction. Such a cooling method may be adopted and applied in various manners according to design requirements in consideration of the amount of heat generated by the power element chips 110.

More specifically, the wall portion 310 of the manifold 300 forms an inlet-side channel C1 and an outlet-side channel C2 by connecting the closed end 330 to the ends of the extended ends 320, and cooling fluid may flow from the inlet-side channel C1 to the outlet-side channel C2 through the through-holes 210.

In this manner, in the wall portion 310 of the manifold 300, a plurality of extended ends 320 extends in the flow direction of the cooling fluid to guide the flow of the cooling fluid, and the closed end 330 is connected to each of the extended ends 320 at an end portion of the flow direction of the cooling fluid to form a closed structure. Accordingly, the opposite side of the closed end 330 forms an open structure. As a result, the wall portion 310 of the manifold 300 may allow the cooling fluid to flow a space formed between the respective extended ends 320, and the flow of the cooling fluid may be changed to pass through the through-holes 210 formed in the heat sink 200 by the closed end 330. In this manner, the cooling fluid may pass through the extended ends 320 through the through-holes 210 formed in the heat sink 200, thereby achieving a jet impingement cooling structure for the heat sink 200.

Meanwhile, the power module 100 is provided with a plurality of power element chips 110, and the respective power element chips 110 may be spaced apart from each other and may be arranged to overlap the extended ends 320.

In the case of the power module 100, as power demand increases, the number of power element chips 110 increases.

In this manner, when the power module 100 is configured to be provided with a plurality of power element chips 110, the respective power element chips 110 may be spaced apart from each other and may overlap a plurality of extended ends 320 forming the wall portion 310 in a state of being spaced apart from each other. Through such a structural configuration, thermal interference of the plurality of power element chips 110 may be prevented. As a result, each of the power element chips 110 may be efficiently cooled through the jet collision effect of the cooling fluid flowing through a space formed between the wall portion 310 of the manifold 300 and the heat sink 200.

Here, a structural configuration in which the power element chips 110 are arranged to overlap the respective extended ends 320 of the manifold 300 may be implemented by arrangement of the power element chips 110 on the circuit substrate 120. Accordingly, in the power module 100, the pattern of the circuit substrate 120 may be set in consideration of the arrangement of the power element chips 110, or the shape of the wall portion 310 of the manifold 300 may be formed in consideration of the position of each of the power element chips 110.

That is, in order to optimize cooling of the power module 100, when the position of each of the power element chips 110 and the shape of the wall portion 310 of the manifold 300 are considered, a cooling structure may be configured such that the power element chips 110 are cooled with high efficiency according to the flow of the cooling fluid flowing through the inside of the manifold 300.

Through such a structural configuration, the power element chips 110 and the extended ends 320 of the manifold 300 may be formed to overlap each other, thereby not only securing cooling efficiency but also preventing unnecessary package increase when the manifold 300 is designed to achieve optimal cooling performance.

In addition, an area of each of the power element chips 110 or a thickness of each of the extended ends 320 may be set depending on the amount of heat generated by the power element chips 110. In the present disclosure, the cooling effect on the power element chips 110 may be adjusted by an area in which the power element chips 110 and the extended ends 320 overlap each other. Accordingly, the amount of heat generated by the power element chips 110 may be ascertained in advance through experiments, and the area of each of the power element chips 110 or the thickness of each of the extended ends 320 may be adjusted by required cooling conditions depending on the amount of heat generated by the power element chips 110, thereby adjusting the overlapping area between the power element chips 110 and the extended ends 320 and satisfying the required cooling conditions.

Meanwhile, as one embodiment according to the present disclosure, the manifold 300 includes a pair of extended ends 320, and the pair of extended ends 320 is connected to the closed end 330. Further, the power element chip 110 of the power module 100 is provided in plural, and the respective power element chips 110 may be arranged to be spaced apart from each other on different extended ends 320.

As shown in FIG. 3, the wall portion 310 is provided with a pair of extended ends 320, and the extended ends 320 are connected to each other through the closed end 330, thereby achieving a structure capable of switching the flow direction of the cooling fluid.

When the power element chip 110 of the power module 100 is provided in plural, the respective power element chips 110 are arranged on different extended ends 320 so as to avoid thermal interference between the power element chips 110, and a cooling effect obtained by the cooling fluid flowing through a space formed between the respective extended ends 320 and the heat sink 200 may be applied to the respective power element chips 110.

In addition, when the number of power element chips 110 needs to be configured in plural on each of the extended ends 320, a plurality of power element chips 110 may be arranged to be spaced apart from each other on each of the extended ends 320.

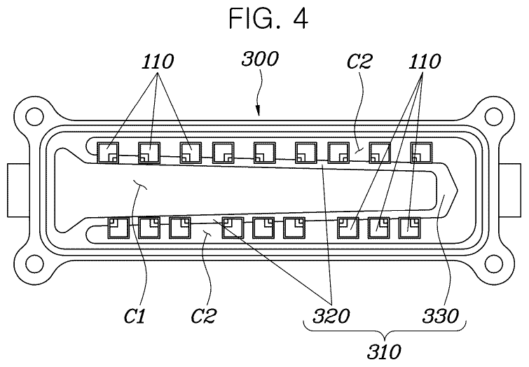

As shown in FIG. 4, the wall portion 310 of the manifold 300 is provided with a pair of extended ends 320, and a plurality of power element chips 110 may be distributed to the pair of extended ends 320. Here, the power element chips 110 are arranged to be spaced apart from each other on each of the extended ends 320 so as to avoid thermal interference therebetween, thereby efficiently cooling each of the power element chips 110.

In the present disclosure, the power element chips 110 of the power module 100 are provided in an even number, and the respective power element chips 110 may be spaced apart from each other on each of the pair of extended ends 320.

In this manner, since the plural power element chips 110 are provided in an even number, the power element chips may be evenly arranged on the pair of extended ends 320. Through such a structural configuration, even if a plurality of power element chips 110 is provided, it is possible to prevent one power element chip 110 from being overcooled or not cooled, and to achieve a uniform cooling effect for each of the power element chips 110, thereby optimizing performance of the power module 100.

Meanwhile, the power element chips 110 of the power module 100 may be arranged so as to overlap portions in which the through-holes 210 are formed in the heat sink 200.

That is, the cooling fluid flowing through the inside of the manifold 300 passes through the extended ends 320 through the through-holes 210 in the heat sink 200, thereby implementing jet impingement cooling for the heat sink 200.

In this manner, since the heat sink 200 has high cooling efficiency in portions in which the through-holes 210 are formed, the power element chips 110 may secure cooling efficiency thereof by overlapping the portions in which the through-holes 210 are formed in the heat sink 200 on the extended ends 320 of the manifold 300.

In addition, since a plurality of through-holes 210 is formed in the heat sink 200, the power element chips 110 may be arranged to overlap the plurality of through-holes 210.

Meanwhile, in the wall portion 310 of the manifold 300, the respective extended ends 320 may extend to gradually approach each other with an angle formed therebetween.

In this manner, the wall portion 310 may be configured such that the width of the wall portion gradually decreases in the flow direction of the cooling fluid as the respective extended ends 320 gradually approach each other with an angle formed therebetween. Through such a structural configuration, flowability of the cooling fluid introduced into a space between the extended ends 320 of the wall portion 310 may be improved by the shape of each of the extended ends 320.

Further, the cooling fluid may smoothly flow through the through-holes 210 in the heat sink 200, which are arranged in a direction away from a direction in which the cooling fluid is introduced, by the shape of each of the extended ends 320, thereby reducing the flow loss of the cooling fluid and improving flowability of the cooling fluid for each of the through-holes 210 disposed along the extended ends 320, thereby increasing cooling performance.

Meanwhile, the through-holes 210 in the heat sink 200 may extend diagonally relative to the flow direction of the cooling fluid in an outward direction, which is the opposite direction of an inward direction in which the respective extended ends 320 connected to each other through the closed end 330 face each other.

As shown in FIG. 3, the through-holes 210 in the heat sink 200 may be formed to extend diagonally. In particular, the through-holes 210 disposed along the extended ends 320 connected to each other through the closed end 330 are arranged in different inclination directions, thereby securing flowability of the cooling fluid passing through each of the extended ends 320 through the through-holes 210.

In detail, the through-holes 210 in the heat sink 200 may extend diagonally toward the outside of the extended ends 320 from the inside thereof. Here, the extended ends 320 face each other toward the inside thereof. In addition, the through-holes 210 arranged along the respective extended ends 320 may extend in opposite directions from the respective extended ends 320 by extending diagonally toward the flow direction of the cooling fluid. Accordingly, as shown in FIG. 3, the through-holes 210 in the heat sink 200 are formed to extend diagonally from the respective extended ends 320, thereby improving flowability of the cooling fluid passing through the extended ends 320.

Meanwhile, as another embodiment of the manifold 300, in the wall portion 310 of the manifold 300, a plurality of extended ends 320 may be arranged, and a plurality of closed ends 330 may alternately connect ends 321 to each other, which are disposed on one side of the manifold, and ends 322 to each other, which are disposed on the other side of the manifold, and the ends 321 and 322 are respectively located on different extended ends 320. In this manner, it is possible to form a plurality of inlet-side channels C1 and a plurality of outlet-side channels C2.

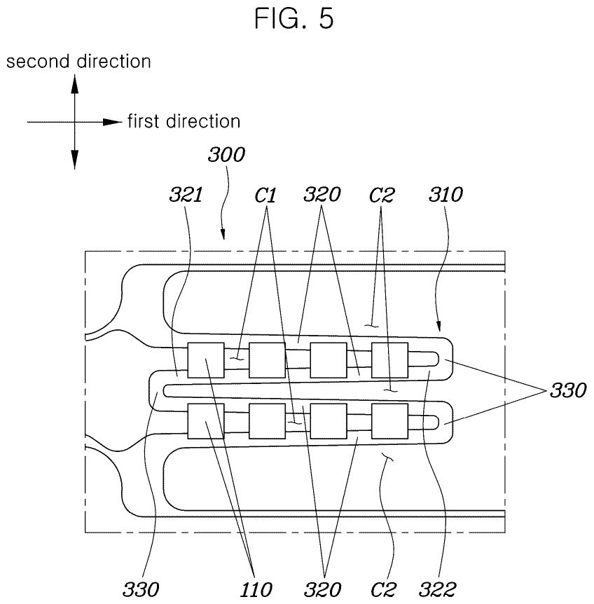

In FIG. 5, the flow direction of the cooling fluid is defined as a first direction, and a direction orthogonal to the first direction is defined as a second direction.

As shown in FIG. 5, a plurality of extended ends 320 is configured to extend in the first direction and is arranged in the second direction, and a plurality of closed ends 330 is alternately connected to one end 321 and the other end 322 of each extended end 320, thereby forming the inlet-side channels C1 and the outlet-side channels C2. Here, the one end 321 may be located on the left side of FIG. 5, and the other end 322 may be located on the right side of FIG. 5.

That is, the wall portion 310 is provided with a plurality of extended ends 320 extending in the first direction, and the closed end 330 is connected to the other end 322 of each extended end 320, thereby forming the inlet-side channel C1 in which one side is open and the other end is closed. In addition, the closed end 330 is connected to one end 321 of each extended end 320, thereby forming the outlet-side channel C2 in which one end is closed and the other end is open.

In the inlet-side channel C1 and the outlet-side channel C2, a plurality of inlet-side channels C1 and a plurality of outlet-side channels C2 may be alternately arranged by allowing the closed ends 330 to be alternately connected to one end 321 and the other end 322 of each extended end 320.

In addition, the wall portion 310 of the manifold 300 may be configured such that the number of closed ends 330 connected to one side of the extended end 320 is one less than the number of closed ends 330 connected to the other side thereof. Accordingly, the inlet-side channel C1 formed by the wall portion 310 in the manifold 300 may be formed to be one less than the outlet-side channel C2.

In this manner, since the number of inlet-side channels C1 is formed to be smaller than that of the outlet-side channels C2, the flow rate and flowability of the cooling fluid flowing into the inlet-side channels C1 may be secured, and the cooling effect may be increased through a pressure change of the cooling fluid flowing from the inlet-side channels C1 to the outlet-side channels C2.

As an embodiment according to the above-described configuration, as shown in FIG. 5, the wall portion 310 may be formed of four extended ends 320 and three closed ends 330 so as to form two inlet-side channels C1 and three outlet-side channels C2.

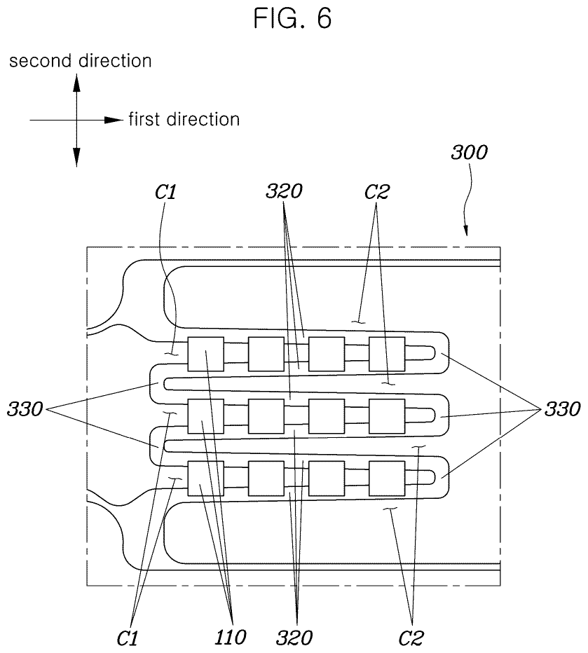

As another embodiment, as shown in FIG. 6, the wall portion 310 may be formed of six extended ends 320 and five closed ends 330 so as to form three inlet-side channels C1 and four outlet-side channels C2.

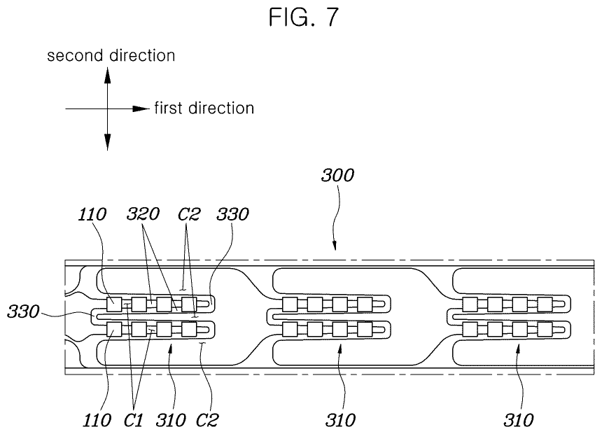

As still another embodiment, as shown in FIG. 7, a plurality of wall portions 310 of the manifold 300 may be formed to be arranged in the longitudinal direction. That is, when a plurality of power modules 100 is configured, a plurality of wall portions 310 of the manifold 300 may be formed according to the number of the power modules 100 and the positions thereof. Here, since the respective wall portions 310 are arranged in the first direction, the cooling fluid may sequentially pass through the respective wall portions 310 so as to cool the respective power modules 100.

The wall portions 310 of the manifold 300 described above may be employed in various embodiments. When the number and shape of the wall portions 310 of the manifold 300 is changed, a cooling structure may be formed according to the position of the power element chips 110 of the power module 100.

Meanwhile, the power element chips 110 of the power module 100 may be arranged to overlap two or more extended ends 320.

Referring to FIG. 5, in a structure in which a plurality of extended ends 320 of the manifold 300 is arranged, the power element chips 110 may be arranged to overlap two or more extended ends 320 so as to expand a cooling range. Such a structural configuration may be determined according to the area of the power element chips 110 or the thickness of the extended ends 320, and in consideration of each condition, the power element chips 110 may be arranged to overlap a plurality of extended ends 320, thereby securing optimal cooling performance of the power element chips 110.

According to the cooling apparatus for the power module 100 of the present disclosure, the manifold 300 is provided for cooling of the power module 100, and when the cooling fluid flows through the inside of the manifold 300, the power module 100 exchanges heat with the cooling fluid, thereby cooling the power module 100.

In particular, through a structural configuration of the manifold 300 optimized for cooling of heat-generating elements of the power module 100, an area unnecessary for cooling may be maximally reduced so as to reduce unnecessary pressure loss of the cooling fluid, cooling efficiency may be increased, and the overall size of a package may be reduced.

As is apparent from the above description, according to a cooling apparatus for a power module of the present disclosure, a manifold is provided for cooling of the power module, and when cooling fluid flows through the inside of the manifold, the power module exchanges heat with the cooling fluid, thereby cooling the power module.

Particularly, since the manifold has a structural configuration optimized for cooling of a heat-generating element of the power module, an area unnecessary for cooling may be maximally reduced so as to reduce unnecessary pressure loss of the cooling fluid, cooling efficiency may be increased, and the overall size of a package may be reduced.

The effects of the present disclosure are not limited to the above-mentioned effects, and other effects not mentioned herein will be clearly understood by those skilled in the art to which the present disclosure pertains from the detailed description of the embodiments. Although the preferred embodiments of the present disclosure have been disclosed for illustrative purposes, those skilled in the art will appreciate that various modifications, additions, and substitutions are possible, without departing from the scope and spirit of the disclosure as disclosed in the accompanying claims.

What is claimed is:

1. A cooling apparatus for a power module, the cooling apparatus comprising:
a power module comprising:
power element chips; and
a circuit substrate bonded to the power element chips;
a heat sink in contact with the circuit substrate, the heat sink having a plurality of through-holes formed therein; and
a manifold configured to allow cooling fluid to flow therethrough and including a wall portion in contact with the circuit substrate,
wherein the wall portion includes:
at least two or more extended ends that extend in a flow direction of the cooling fluid; and
a closed end connected to each of the extended ends, and
wherein the extended ends are configured to partly or completely overlap the power element chips.

2. The cooling apparatus of claim 1, wherein the through-holes extend in a direction intersecting the flow direction of the cooling fluid.

3. The cooling apparatus of claim 1, wherein the wall portion of the manifold forms an inlet-side channel and an outlet-side channel by connecting the closed end to ends of the extended ends, and
wherein the cooling fluid flows from the inlet-side channel to the outlet-side channel through the through-holes.

4. The cooling apparatus of claim 1, wherein the power module comprises a plurality of the power element chips, and
wherein the respective power element chips are spaced apart from each other and are arranged to overlap the extended ends.

5. The cooling apparatus of claim 1,
wherein the manifold includes the extended ends extending in pairs, the pair of extended ends being connected to the closed end, and
wherein the respective power element chips are arranged to be spaced apart from each other at different extended ends.

6. The cooling apparatus of claim 5, wherein the power element chips are provided in an even number, and
wherein the respective power element chips are arranged on the pair of extended ends and spaced apart from each other.

7. The cooling apparatus of claim 1, wherein the power element chips are disposed to overlap portions of the heat sink, the portions having the through-holes formed therein.

8. The cooling apparatus of claim 1, wherein the power element chips or the extended ends are configured such that an area of each of the power element chips or a thickness of each of the extended ends is set according to an amount of heat generated by the power element chips.

9. The cooling apparatus of claim 1, wherein the respective extended ends of the wall portion of the manifold extend to gradually approach each other with an angle formed therebetween.

10. The cooling apparatus of claim 1, wherein the through-holes in the heat sink extend diagonally relative to the flow direction of the cooling fluid in an outward direction opposite to an inward direction in which the respective extended ends connected to each other through the closed end face each other.

11. The cooling apparatus of claim 1, wherein the wall portion of the manifold is configured such that a plurality of the extended ends and a plurality of the closed ends alternately connect ends located on one side of the extended ends and ends located on other side of the extended ends, and
wherein the ends respectively located on the one side and the other side being located on different extended ends, thereby forming a plurality of inlet-side channels and a plurality of outlet-side channels.

12. The cooling apparatus of claim 11, wherein the wall portion of the manifold is configured such that a number of the closed ends connected to the one side of the extended ends is one less than a number of the closed ends connected to the other side of the extended ends.

13. The cooling apparatus of claim 12, wherein the power element chips are arranged to overlap two or more of the extended ends.

14. The cooling apparatus of claim 1, wherein one surface of the heat sink is in contact with the power module, another surface thereof has the through-holes formed therein, and the heat sink is interposed between the power module and the manifold to form a heat transfer structure.

15. The cooling apparatus of claim 1,
wherein the power module comprises a molding part made of an epoxy material and configured to surround the power element chips and the circuit substrate, and
wherein the molding part comprises the wall portion of the manifold.

16. A cooling apparatus, comprising:
a power module comprising:
a power element chip; and
a circuit substrate bonded to the power element chips;
a heat sink in contact with the circuit substrate; and
a manifold including a wall portion in contact with the heat sink, the wall portion configured to draw heat from the heat sink, the manifold configured to direct cooling fluid therethrough and dissipate heat,
wherein the wall portion includes:
extended ends that extend in a flow direction of the cooling fluid; and
a closed end connected to each of the extended ends, and
wherein the extended ends are configured to partly or completely overlap the power element chips.

17. The cooling apparatus of claim 16, wherein the heat sink includes a plurality of through-holes.
